(19) United States
(12) Patent Application Publication
(10) Pub. No.: US 2013/0002356 A1
(43) Pub. Date: Jan. 3, 2013

(54) OPERATIONAL AMPLIFIER

(75) Inventors: Ju-Lin Huang, Hsinchu County (TW); Po-Yu Tseng, Taoyuan County (TW)

(73) Assignee: NOVATEK MICROELECTRONICS CORP., Hsinchu (TW)

(21) Appl. No.: 13/466,129

(22) Filed: May 8, 2012

(30) Foreign Application Priority Data
Jun. 29, 2011 (TW) 100122902

(51) Int. Cl. H03F 3/45

(52) U.S. Cl. 330/261

(57) ABSTRACT

An operational amplifier including a primary differential input pair, a primary tail current source module, N auxiliary differential input pairs, and N auxiliary tail current source modules is disclosed. A first and a second input terminal of the primary differential input pair respectively receive a first and a second input signal, wherein first input signal and the second input signal are differential to each other. The primary tail current source module supplies a tail current to the primary differential input pair during a first time interval. A first and a second input terminal of each of the auxiliary differential input pairs respectively receive the first and the second input signal. Each of the auxiliary tail current source modules supplies an auxiliary tail current to the corresponding auxiliary differential input pair during a second time interval. The first time interval and the second time interval partially overlap each other.

### CROSS-REFERENCE TO RELATED APPLICATION

This application claims the priority benefit of Taiwan application serial no. 100122902, filed on Jun. 29, 2011. The entirety of the above-mentioned patent application is hereby incorporated by reference herein and made a part of this specification.

### BACKGROUND OF THE INVENTION

1. Field of the Invention

The invention generally relates to an operational amplifier, and more particularly, to an operational amplifier with differential input pairs.

2. Description of Related Art

FIG. 1 is a circuit diagram of a conventional differential amplifier 100. Referring to FIG. 1, the differential amplifier 100 includes a differential input pair 110, a tail current source IT, and an active load 120. The differential input pair 110 is composed of transistors N1 and N2, and the control terminals (gates) of the transistors N1 and N2 respectively receive input signals VI+ and VI− which are differential to each other. The tail current source IT is coupled between the differential input pair 110 and a reference voltage GND and supplies a tail current to the differential input pair 110. The output terminal of the differential amplifier 100 generates an output signal Vo.

Regardless of whether the conventional differential amplifier 100 is applied as a buffer, a comparator, or any other device, electronic components (for example, the transistors N1 and N2) therein deteriorate due to long-time or high-frequency operation, and accordingly the reliability of the differential amplifier 100 decreases. Moreover, decrease in the reliability of the differential amplifier 100 shortens the lifespan of the electronic product adopting the differential amplifier 100. Thereby, how to effectively prolong the lifespan of an operational amplifier in an electronic product has become one of the major subjects in the industry.

### SUMMARY OF THE INVENTION

Accordingly, the invention is directed to an operational amplifier, where the lifespan of the operational amplifier is effectively prolonged.

The invention is directed to a rail to rail operational amplifier, where the lifespan of the rail to rail operational amplifier is effectively prolonged.

The invention provides an operational amplifier including a primary differential input pair, a primary tail current source module, N auxiliary differential input pairs, and N auxiliary tail current source modules, wherein N is a positive integer. The primary differential input pair has a common terminal, a first differential terminal, a second differential terminal, a first input terminal, and a second input terminal, wherein the first input terminal and the second input terminal respectively receive a first input signal and a second input signal that are differential to each other. The primary tail current source module is coupled to the common terminal of the primary differential input pair and supplies a tail current to the primary differential input pair during a first time interval. Each of the auxiliary differential input pairs has a common terminal, a first differential terminal, a second differential terminal, a first input terminal, and a second input terminal, wherein the first input terminal and the second input terminal respectively receive the first input signal and the second input signal, and the first differential terminal and the second differential terminal are respectively coupled to the first differential terminal and the second differential terminal of the primary differential input pair. The auxiliary tail current source modules are respectively coupled to the common terminals of the auxiliary differential input pairs, and each of the auxiliary tail current source modules supplies an auxiliary tail current to the corresponding auxiliary differential input pair during a second time interval, wherein the first time interval and the second time interval partially overlap each other.

The invention provides a rail to rail operational amplifier including a first operational amplifier and a second operational amplifier. The first operational amplifier includes a first primary differential input pair, a first primary tail current source module, N first auxiliary differential input pairs, and N first auxiliary tail current source modules. The first primary differential input pair has a common terminal, a first differential terminal, a second differential terminal, a first input terminal, and a second input terminal, wherein the first input terminal and the second input terminal respectively receive a first input signal and a second input signal that are differential to each other. The first primary tail current source module is coupled between the common terminal of the first primary differential input pair and a first reference voltage and supplies a first tail current to the first primary differential input pair during a first time interval. Each of the first auxiliary differential input pairs has a common terminal, a first differential terminal, a second differential terminal, a first input terminal, and a second input terminal, wherein the first input terminal and the second input terminal respectively receive the first input signal and the second input signal, and the first differential terminal and the second differential terminal are respectively coupled to the first differential terminal and the second differential terminal of the first primary differential input pair. The first auxiliary tail current source modules are respectively coupled between the common terminals of the first auxiliary differential input pairs and the first reference voltage, and each of the auxiliary tail current source modules supplies a first auxiliary tail current to the corresponding first auxiliary differential input pair during a second time interval. The second operational amplifier includes a second primary differential input pair, a second primary tail current source module, M second auxiliary differential input pairs, and M second auxiliary tail current source modules. The second primary differential input pair has a common terminal, a first differential terminal, a second differential terminal, a first input terminal, and a second input terminal, wherein the first input terminal and the second input terminal respectively receive the first input signal and the second input signal. The second primary tail current source module is coupled between the common terminal of the second primary differential input pair and the second reference voltage and supplies a second tail current to the second primary differential input pair during the second time interval. Each of the second auxiliary differential input pairs has a common terminal, a first differential terminal, a second differential terminal, a first input terminal, and a second input terminal, wherein the first input terminal and the second input terminal respectively receive the first input signal and the second input signal, and the first differential terminal and the second differential terminal are respectively coupled to the first differential terminal and the second differential terminal of the second primary differential input pair. The second auxiliary tail current source modules are respectively coupled between the common terminals of the second auxiliary differential input pairs and the second reference voltage, and each of the auxiliary tail current source modules supplies a second auxiliary tail current to the corresponding second auxiliary differential input pair during the first time interval. Herein the first time interval and the second time interval partially overlap each other.

As described above, in the invention, one or more auxiliary differential input pairs are disposed outside a primary differential input pair of an operational amplifier, and the primary differential input pair and the auxiliary differential input pairs are alternatively used by controlling the supply of tail currents to the primary differential input pair and the auxiliary differential input pairs. Thereby, no electrical attenuation will be produced in the primary differential input pair of the operational amplifier due to long-time operation, and accordingly the lifespan of the operational amplifier is effectively prolonged.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a conventional differential amplifier 100.

FIG. 2 is a diagram of an operational amplifier 200 according to an embodiment of the invention.

FIG. 3 is a diagram of an operational amplifier 300 according to another embodiment of the invention.

FIG. 4 is a diagram of an operational amplifier 400 according to yet another embodiment of the invention.

FIG. 5 illustrates an operation waveform of a bias voltage supplier 370 according to an embodiment of the invention.

FIG. 6A and FIG. 6B are diagrams of a rail to rail operational amplifier according to an embodiment of the invention.

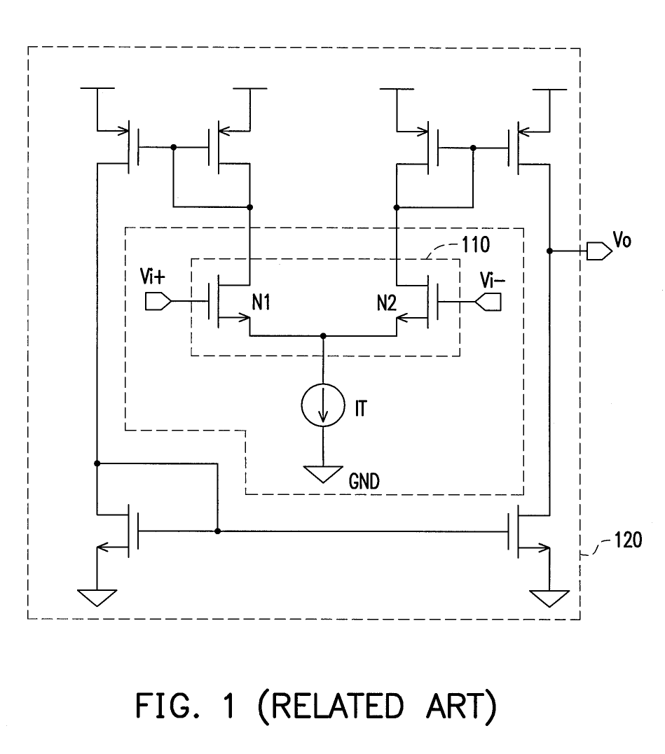

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

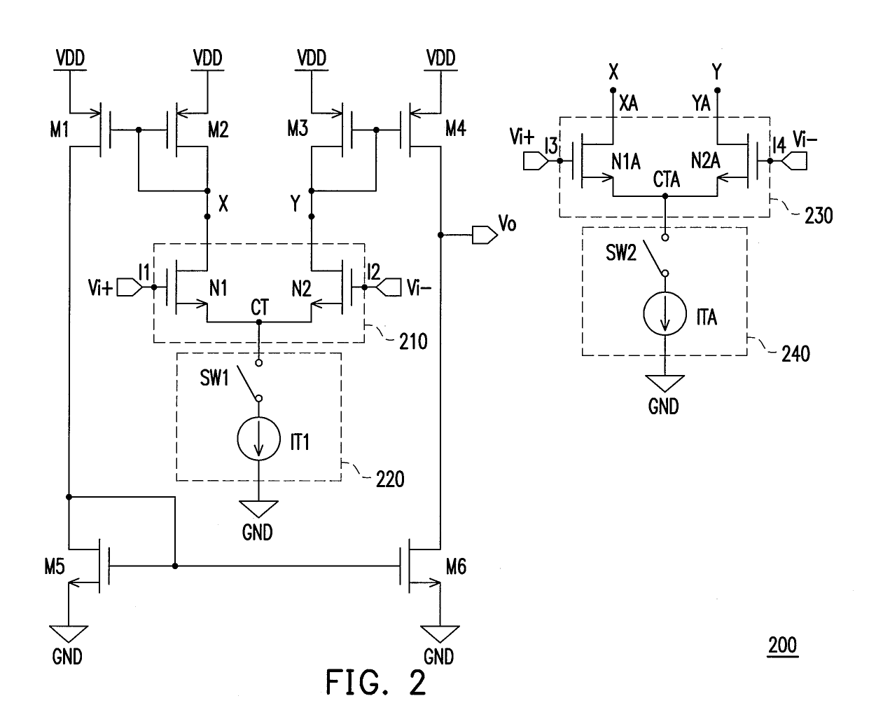

FIG. 2 is a diagram of an operational amplifier 200 according to an embodiment of the invention. Referring to FIG. 2, the operational amplifier 200 includes a primary differential input pair 210, a primary tail current source module 220, an auxiliary differential input pair 230, and an auxiliary tail current source module 240. The primary differential input pair 210 has a common terminal CT, differential terminals X and Y, and input terminals I1 and I2. The input terminals I1 and I2 respectively receive input signals Vi+ and Vi−, wherein the input signals Vi+ and Vi− are differential to each other. The common terminal CT is connected to the primary tail current source module 220. The differential terminals X and Y are respectively connected to transistors M2 and M3.

Besides being coupled to the common terminal CT of the primary differential input pair 210, the primary tail current source module 220 is also coupled to a reference voltage GND. In the present embodiment, the reference voltage GND is a ground voltage. The primary tail current source module 220 supplies a tail current to the primary differential input pair 210 via the common terminal CT. To be specific, in the present embodiment, the primary tail current source module 220 supplies the tail current to the primary differential input pair 210 via the common terminal CT during a first time interval and stops supplying the tail current to the primary differential input pair 210 via the common terminal CT outside the first time interval. When the primary differential input pair 210 is supplied with the tail current during the first time interval, the primary differential input pair 210 can work effectively. Contrarily, when the primary differential input pair 210 is not supplied with the tail current outside the first time interval, the primary differential input pair 210 does not work.

The primary differential input pair 210 includes primary input transistors N1 and N2. The control terminal (gate) of the primary input transistor N1 receives the input signal Vi+, the first terminal (source/drain) thereof is coupled to a reference voltage VDD through the transistor M2, and the second terminal (drain/source) thereof is coupled to the common terminal CT of the primary differential input pair 210. The control terminal (gate) of the primary input transistor N2 receives the input signal Vi−, the first terminal (source/drain) thereof is coupled to the reference voltage VDD through a transistor M1, and the second terminal (drain/source) thereof is coupled to the common terminal CT of the primary differential input pair 210. In the present embodiment, the reference voltage VDD may be an operating power supply.

The primary tail current source module 220 includes a current source IT1 and a switch SW1. The current source IT1 is coupled between the common terminal CT of the primary differential input pair 210 and the reference voltage GND and generates the tail current. The switch SW1 is serially connected on a coupling path between the current source IT1 and the common terminal CT of the primary differential input pair 210 and turns on or off the path for the tail current to run towards the primary differential input pair 210. Namely, during the first time interval, the switch SW1 is turned on so that the tail current supplied by the current source IT1 can run towards the primary differential input pair 210. Contrarily, the switch SW1 is turned off outside the first time interval so that the tail current supplied by the current source IT1 cannot run towards the primary differential input pair 210.

Similarly, the auxiliary differential input pair 230 has a common terminal CTA, differential terminals XA and YA, and input terminals I3 and I4. The input terminals I3 and I4 of the auxiliary differential input pair 230 respectively receive the input signals Vi+ and Vi−, and the differential terminals XA and YA thereof are respectively coupled to the differential terminals X and Y of the primary differential input pair 210.

The auxiliary tail current source module 240 is coupled to the common terminal CTA of the auxiliary differential input pair 230. It should be noted that the auxiliary tail current source module 240 supplies an auxiliary tail current to the auxiliary differential input pair 230 during a second time interval. Herein the second time interval partially overlaps the first time interval.

To be specific, when it is within the first time interval but not the second time interval, the auxiliary tail current source module 240 does not supply the auxiliary tail current to the auxiliary differential input pair 230, and accordingly the auxiliary differential input pair 230 does not work. When the first time interval is about to end and the second time interval is entered, the auxiliary tail current source module 240 starts to supply the auxiliary tail current to the auxiliary differential input pair 230, and accordingly the auxiliary differential input pair 230 starts to work. After the first time interval is over, the primary tail current source module 220 stops supplying the tail current to the primary differential input pair 210, and the auxiliary tail current source module 240 continues to supply the auxiliary tail current to the auxiliary differential input pair 230. Namely, during the portion of the second time interval which does not overlap the first time interval, the auxiliary differential input pair 230 alone receives the input signals Vi+ and Vi−, and the primary differential input pair 210 does not work.

It can be understood based on foregoing description that the primary differential input pair 210 and the auxiliary differential input pair 230 can be controlled to work alternatively by periodically switching the first time interval and the second time interval, so that the continuous working time of each differential input pair can be shortened and accordingly the lifespan of the operational amplifier 200 can be prolonged.

It should be mentioned that the first time interval is partially overlapped with the second time interval in order to avoid any mis-operation caused by discontinuity of the time interval switching operation of the operational amplifier 200. Namely, the first time interval is partially overlapped with the second time interval to ensure that at least one differential input pair is working during any time interval.

The numbers of the auxiliary differential input pair 230 and the auxiliary tail current source module 240 are not limited to one. If the circuit layout area permits, a designer can design one or more auxiliary differential input pairs 230 and one or more auxiliary tail current source modules 240 to alternate with the primary differential input pair 210.

In the present embodiment, the auxiliary differential input pair 230 includes auxiliary input transistors N1A and N2A. The control terminal (gate) of the auxiliary input transistor N1A receives the input signal Vi+, the first terminal (source/drain) thereof is coupled to the differential terminal XA of the auxiliary differential input pair 230 and coupled to the reference voltage VDD via the transistor M2, and the second terminal (drain/source) thereof is coupled to the common terminal CTA of the auxiliary differential input pair 230. The control terminal (gate) of the auxiliary input transistor N2A receives the input signal Vi−, the first terminal (source/drain) thereof is coupled to the differential terminal YA of the auxiliary differential input pair 230 and coupled to the reference voltage VDD via the transistor M3, and the second terminal (drain/source) thereof is coupled to the common terminal CTA of the auxiliary differential input pair 230.

The auxiliary tail current source module 240 includes a switch SW2 and a current source ITA. The current source ITA is coupled between the common terminal CTA of the auxiliary differential input pair 230 and the reference voltage GND and generates the auxiliary tail current. The switch SW2 is serially connected on the coupling path between the current source ITA and the common terminal CTA of the auxiliary differential input pair 230 and turns on or off the path for the auxiliary tail current to run towards the auxiliary differential input pair 230.

It should be mentioned that the operational amplifier 200 in the present embodiment further includes an active load composed of transistors M1-M6. Besides, the operational amplifier 200 generates an output signal Vo on an output terminal (i.e., the coupling node between the transistor M4 and the transistor M6) thereof.

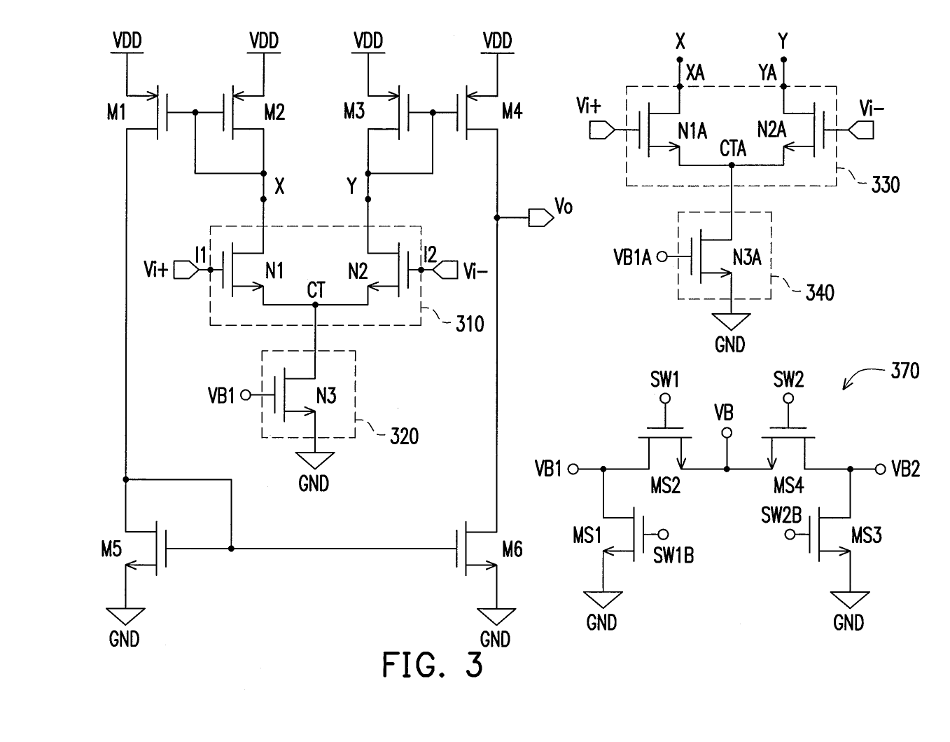

FIG. 3 is a diagram of an operational amplifier 300 according to another embodiment of the invention. Referring to FIG. 3, the operational amplifier 300 includes a primary differential input pair 310, a primary tail current source module 320, an auxiliary differential input pair 330, an auxiliary tail current source module 340, and a bias voltage supplier 370. The implementations of the primary differential input pair 310 and the auxiliary differential input pair 330 are similar to the implementations of the primary differential input pair 210 and the auxiliary differential input pair 230 in previous embodiment therefore will not be described herein. In the present embodiment, the primary tail current source module 320 is a primary tail current source composed of a transistor N3. The primary tail current source module 320 is coupled between the common terminal CT of the primary differential input pair 310 and the reference voltage GND. The primary tail current source generates a tail current according to a bias voltage VB1.

Namely, the control terminal (gate) of the transistor N3 receives the bias voltage VB1, and the first terminal and the second terminal thereof are serially connected between the common terminal CT of the primary differential input pair 310 and the reference voltage GND. The value of the tail current generated by the transistor N3 is controlled by the voltage level of the bias voltage VB1. However, the tail current generated by the transistor N3 may also be cut off by providing a bias voltage VB1 at an appropriate level. In the present embodiment, the transistor N3 is an N-type metal-oxide-semiconductor field-effect transistor (MOSFET). Thus, the tail current generated by the transistor N3 can be cut off by supplying a bias voltage VB1 at the ground level (0V).

Additionally, the auxiliary tail current source module 340 is an auxiliary tail current source composed of a transistor N3A. The auxiliary tail current source is coupled between the common terminal CTA of the auxiliary differential input pair 330 and the reference voltage GND. The auxiliary tail current source generates an auxiliary tail current according to a bias voltage VB2.

Namely, the control terminal (gate) of the transistor N3A receives the bias voltage VB2, and the first terminal and the second terminal thereof are serially connected between the common terminal CTA of the auxiliary differential input pair 330 and the reference voltage GND. Similarly, the value of the auxiliary tail current generated by the transistor N3A is controlled by the voltage level of the bias voltage VB2. However, the auxiliary tail current generated by the transistor N3A may be cut off by providing a bias voltage VB2 at an appropriate level. In the present embodiment, the auxiliary tail current generated by the transistor N3A can be cut off by supplying a bias voltage VB2 at the ground level (0V).

The bias voltage supplier 370 supplies the bias voltages VB1 and VB2 for controlling the tail current and the auxiliary tail current. The bias voltage supplier 370 receives a primary bias voltage VB and switch control signals SW1, SW2, SW1B, and SW2B. The bias voltage supplier 370 transmits the primary bias voltage VB as the bias voltage VB1 during the first time interval and transmits the primary bias voltage VB as the bias voltage VB2 during the second time interval according to the switch control signals SW1, SW2, SW1B, and SW2B.

The bias voltage supplier 370 includes switches composed of transistors MS1-MS4. In the switch composed of the transistor MS1, the control terminal receives the switch control signal SW1B, the first terminal receives the reference voltage GND, and the second terminal supplies the bias voltage VB1. In the switch composed of the transistor MS2, the control terminal receives the switch control signal SW1, the first terminal is coupled to the terminal of the transistor MS1 for generating the bias voltage VB1, and the second terminal receives the primary bias voltage VB. In the switch composed of the transistor MS3, the control terminal receives the switch control signal SW2B, the first terminal receives the reference voltage GND, and the second terminal supplies the bias voltage VB2. In the switch composed of the transistor MS4, the first terminal is coupled to the terminal of the transistor MS3 for generating the bias voltage VB2, the second terminal receives the primary bias voltage VB, and the control terminal receives the switch control signal SW2. Herein the switch control signal SW1B is an inverted signal of the switch control signal SW1, and the switch control signal SW2B is an inverted signal of the switch control signal SW2.

Additionally, in the present embodiment, during the first time interval, the switch composed of the transistor MS1 is turned off, and the switch composed of the transistor MS1 is turned on. During the second time interval, the switch composed of the transistor MS3 is turned off, and the switch composed of the transistor MS4 is turned on. Namely, the first time interval can be controlled by controlling the switch control signals SW1 and SW1B, and the second time interval can be controlled by controlling the switch control signals SW2 and SW2B.

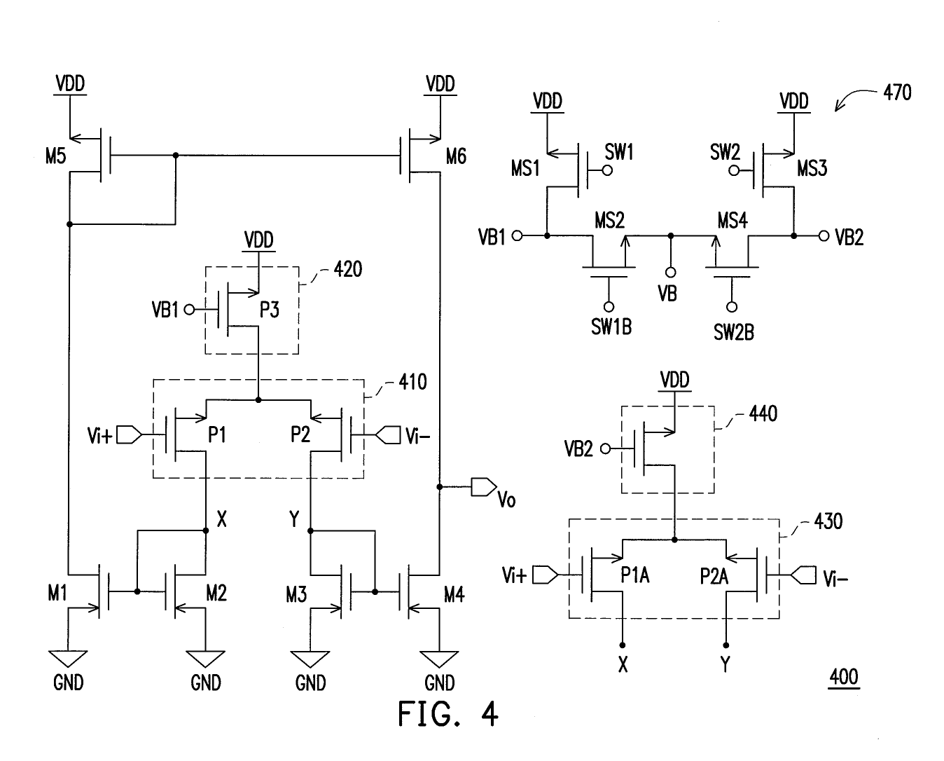

FIG. 4 is a diagram of an operational amplifier 400 according to yet another embodiment of the invention. Referring to FIG. 4, the operational amplifier 400 includes a primary differential input pair 410, a primary tail current source module 420, an auxiliary differential input pair 430, an auxiliary tail current source module 440, and a bias voltage supplier 470. The transistors in the present embodiment are complementary to the corresponding transistors in the operational amplifier 300 described in previous embodiment. For example, the primary differential input pair 410 is composed of P-type primary input transistors P1 and P2 that are complementary to the N-type primary input transistors constituting the primary differential input pair 310. Besides, unlike the primary tail current source module 320 in the operational amplifier 300 (which is composed of an N-type transistor N3), the primary tail current source module 420 is composed of a P-type transistor P3. The same applies to the other components and will not be described herein.

When all the transistors are replaced with complementary transistors, the terminals originally connected to the reference voltage VDD in the operational amplifier 300 are connected to the reference voltage GND in the present embodiment, and contrarily, the terminals originally connected to the reference voltage GND in the operational amplifier 300 are connected to the reference voltage VDD in the present embodiment.

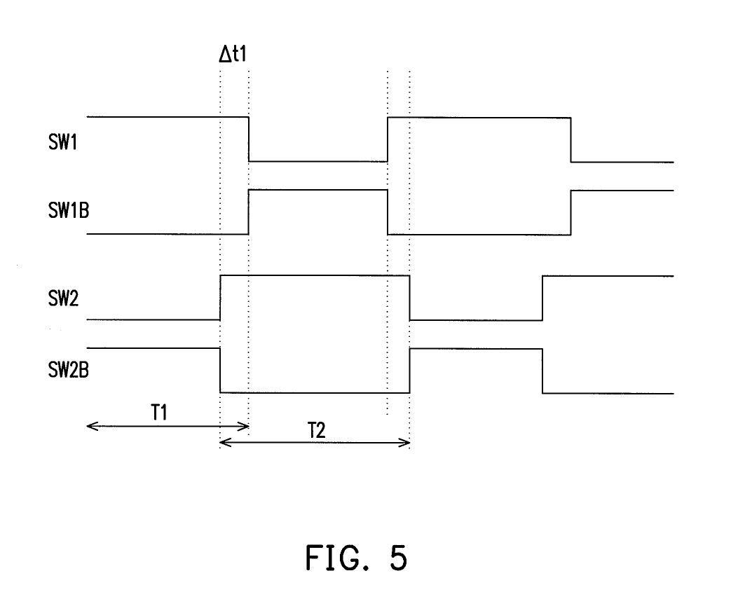

FIG. 5 illustrates an operation waveform of a bias voltage supplier 370 according to an embodiment of the invention. Referring to both FIG. 3 and FIG. 5, during the first time interval T1, the switch control signal SW1 presents a logic high level so that the bias voltage VB1 is equal to the primary bias voltage VB. Besides, during the first time interval T1 and outside the second time interval T2, the switch control signal SW2 presents a logic low level so that the bias voltage VB2 is equal to the reference voltage GND.

During the overlapped portion t1 of the first time interval T1 and the second time interval T2, because the switch control signal SW2 transits into the logic high level, the bias voltage VB2 becomes equal to the primary bias voltage VB. While during the second time interval T2 and outside the first time interval T1, because the switch control signal SW1 transits into the logic low level, the bias voltage VB1 becomes equal to the reference voltage GND.

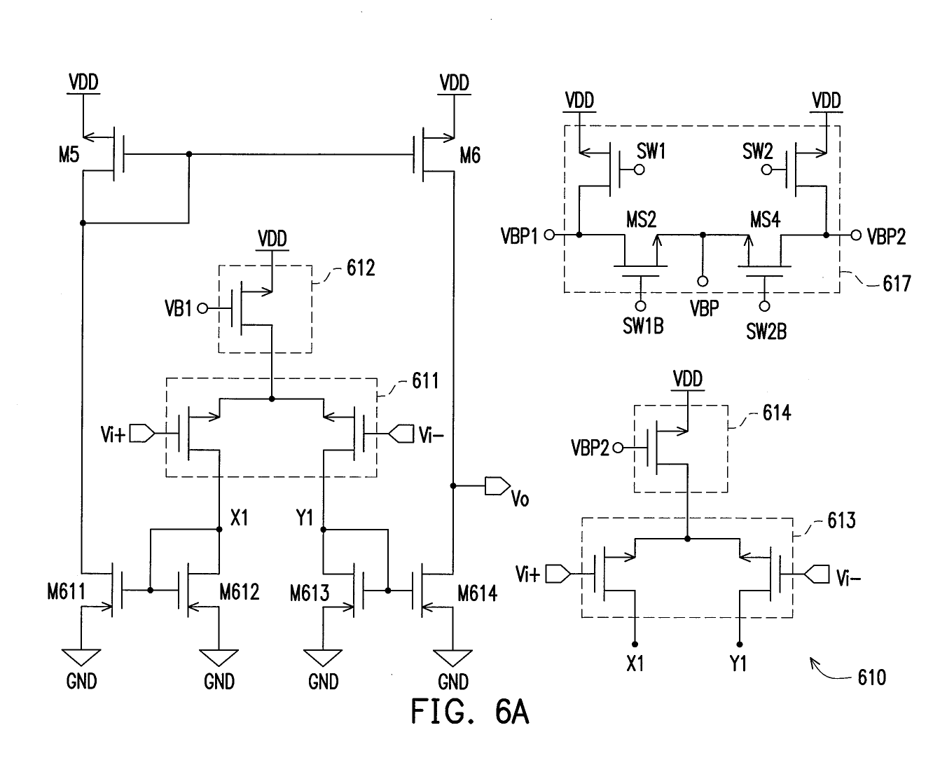

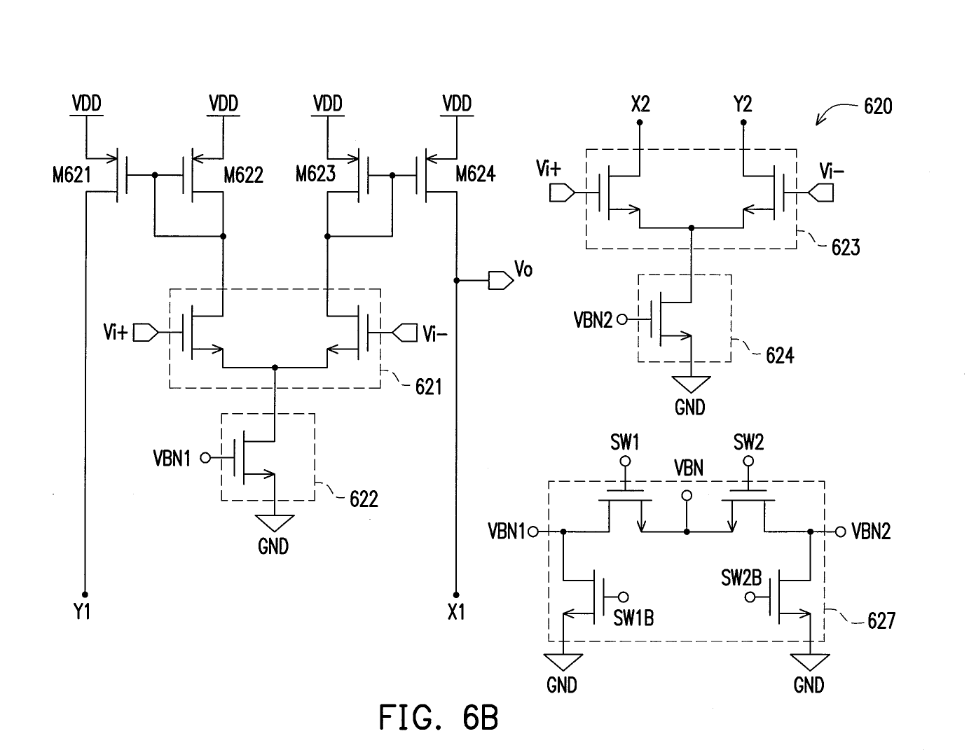

FIG. 6A and FIG. 6B are diagrams of a rail to rail operational amplifier according to an embodiment of the invention, wherein FIG. 6A illustrates an operational amplifier 610, and FIG. 6B illustrates an operational amplifier 620. Referring to FIG. 6A and FIG. 6B, the operational amplifier 610 includes a primary differential input pair 611, a primary tail current source module 612, an auxiliary differential input pair 613, an auxiliary tail current source module 614, and a bias voltage supplier 617. The structures and operations of the primary differential input pair 611, the primary tail current source module 612, the auxiliary differential input pair 613, the auxiliary tail current source module 614, and the bias voltage supplier 617 have been described in detail in foregoing embodiments therefore will not be described herein.

The operational amplifier 610 further includes an active load composed of transistors M611-M616, wherein the active load is connected to the differential terminals X1 and Y1 of the primary differential input pair 611.

The operational amplifier 620 includes a primary differential input pair 621, a primary tail current source module 622, an auxiliary differential input pair 623, an auxiliary tail current source module 624, and a bias voltage supplier 627. The structures and operations of the primary differential input pair 621, the primary tail current source module 622, the auxiliary differential input pair 623, the auxiliary tail current source module 624, and the bias voltage supplier 627 have been described in detail in foregoing embodiments therefore will not be described herein. It should be noted that the transistors adopted by different components in the operational amplifier 610 and the operational amplifier 620 are complementary to each other. For example, the primary differential input pair 621 is composed of N-type primary input transistors, while the primary differential input pair 611 is composed of P-type primary input transistors.

Additionally, the operational amplifier 620 further includes an active load composed of transistors M621-M624. The transistors M622 and M623 are connected to the differential terminals X2 and Y2 of the primary differential input pair 621, and the transistors M621 and M624 are respectively connected to the differential terminals Y1 and X1 of the primary differential input pair 611 in the operational amplifier 610.

In the present embodiment, the primary tail current source module 612 and the auxiliary tail current source module 614 of the operational amplifier 610 and the primary tail current source module 622 and the auxiliary tail current source module 624 of the operational amplifier 620 respectively receive bias voltages VBP1, VBP2, VBN1, and VBN2 to control the generated currents. The bias voltage supplier 617 generates the bias voltages VBP1 and VBP2 according to a primary bias voltage VBP and switch control signals SW1, SW1B, SW2, and SW2B, and the bias voltage supplier 627 generates the bias voltages VBN1 and VBN2 according to a primary bias voltage VBN and switch control signals SW1, SW1B, SW2, and SW2B.

As described above, in the invention, auxiliary differential input pairs are disposed outside a primary differential input pair, and the operation states of the primary differential input pair and the auxiliary differential input pairs are alternated by controlling the tail current and auxiliary tail currents running through the primary differential input pair and the auxiliary differential input pairs. Thereby, the same differential input pair is avoided to work for a long time. In addition, when multiple differential input pairs alternatively work, attenuation of electronic components in the differential input pairs is prevented, and accordingly the lifespan of the operational amplifier is prolonged.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An operational amplifier, comprising:
a primary differential input pair, having a common terminal, a first differential terminal, a second differential terminal, a first input terminal, and a second input terminal, wherein the first input terminal and the second input terminal respectively receive a first input signal and a second input signal, and the first input signal and the second input signal are differential to each other;
a primary tail current source module, coupled to the common terminal of the primary differential input pair, and supplying a tail current to the primary differential input pair during a first time interval;
N auxiliary differential input pairs, wherein N is a positive integer, and each of the auxiliary differential input pairs has a common terminal, a first differential terminal, a second differential terminal, a first input terminal, and a second input terminal, wherein the first input terminal and the second input terminal respectively receive the first input signal and the second input signal, and the first differential terminal and the second differential terminal are respectively coupled to the first differential terminal and the second differential terminal of the primary differential input pair; and
N auxiliary tail current source modules, respectively coupled to the common terminals of the auxiliary differential input pairs, wherein each of the auxiliary tail current source modules supplies an auxiliary tail current to the corresponding auxiliary differential input pair during a second time interval,
wherein the first time interval and the second time interval partially overlap each other.

2. The operational amplifier according to claim 1, wherein the primary differential input pair comprises:
a first primary input transistor, having a first terminal, a second terminal, and a control terminal, wherein the control terminal receives the first input signal, the first terminal is coupled to a first reference voltage, and the second terminal is coupled to the common terminal of the primary differential input pair; and
a second primary input transistor, having a first terminal, a second terminal, and a control terminal, wherein the control terminal receives the second input signal, the first terminal is coupled to the first reference voltage, and the second terminal is coupled to the common terminal of the primary differential input pair.

3. The operational amplifier according to claim 2, wherein each of the auxiliary differential input pairs comprises:
a first auxiliary input transistor, having a first terminal, a second terminal, and a control terminal, wherein the control terminal receives the first input signal, the first terminal is coupled to the first reference voltage, and the second terminal is coupled to the common terminal of the auxiliary differential input pair; and
a second auxiliary input transistor, having a first terminal, a second terminal, and a control terminal, wherein the control terminal receives the second input signal, the first terminal is coupled to the first reference voltage, and the second terminal is coupled to the common terminal of the auxiliary differential input pair.

4. The operational amplifier according to claim 2, wherein the primary tail current source module comprises:
a current source, coupled between the common terminal of the primary differential input pair and a second reference voltage, and generating the tail current; and
a switch, serially connected on a coupling path between the current source and the common terminal of the primary differential input pair, and turning on or off a path for the tail current to run towards the primary differential input pair.

5. The operational amplifier according to claim 2, wherein each of the auxiliary tail current source modules comprises:
a current source, coupled between the common terminal of the auxiliary differential input pair and a second reference voltage, and generating the auxiliary tail current; and
a switch, serially connected on a coupling path between the current source and the common terminal of the auxiliary differential input pair, and turning on or off a path for the auxiliary tail current to run towards the auxiliary differential input pair.

6. The operational amplifier according to claim 2, wherein the primary tail current source module comprises:
a primary tail current source, coupled between the common terminal of the primary differential input pair and a second reference voltage, and generating the tail current according to a first bias voltage.

7. The operational amplifier according to claim 6, wherein each of the auxiliary tail current source modules comprises:
an auxiliary tail current source, coupled between the common terminal of the corresponding auxiliary differential input pair and the second reference voltage, and generating the auxiliary tail current according to a second bias voltage.

8. The operational amplifier according to claim 7 further comprising:
a bias voltage supplier, receiving a primary bias voltage and a switch control signal, and generating the first bias voltage during the first time interval and generating the second bias voltage during the second time interval by using the primary bias voltage according to the switch control signal.

9. The operational amplifier according to claim 8, wherein the bias voltage supplier comprises:
a first switch, having a control terminal for receiving a first switch control signal in the switch control signal, a first terminal for receiving the second reference voltage, and a second terminal for supplying the first bias voltage;
a second switch, having a first terminal coupled to the second terminal of the first switch, a second terminal for receiving the primary bias voltage, and a control terminal for receiving an inverted signal of the first switch control signal;
a third switch, having a control terminal for receiving an inverted signal of a second switch control signal in the switch control signal, a first terminal for receiving the second reference voltage, and a second terminal for supplying the second bias voltage; and
a fourth switch, having a first terminal coupled to the second terminal of the third switch, a second terminal for receiving the primary bias voltage, and a control terminal for receiving the second switch control signal.

10. The operational amplifier according to claim 9, wherein during the first time interval, the first switch is turned off and the second switch is turned on, and during the second time interval, the third switch is turned off and the fourth switch is turned on.

11. A rail to rail operational amplifier, comprising:
a first operational amplifier, comprising:
a first primary differential input pair, having a common terminal, a first differential terminal, a second differential terminal, a first input terminal, and a second input terminal, wherein the first input terminal and the second input terminal respectively receive a first input signal and a second input signal, and the first input signal and the second input signal are differential to each other;
a first primary tail current source module, coupled between the common terminal of the first primary differential input pair and a first reference voltage, and supplying a first tail current to the first primary differential input pair during a first time interval;
N first auxiliary differential input pairs, wherein N is a positive integer, and each of the first auxiliary differential input pairs has a common terminal, a first differential terminal, a second differential terminal, a first input terminal, and a second input terminal, wherein the first input terminal and the second input terminal respectively receive the first input signal and the second input signal, and the first differential terminal and the second differential terminal are respectively coupled to the first differential terminal and the second differential terminal of the first primary differential input pair; and
N first auxiliary tail current source modules, respectively coupled between the common terminals of the first auxiliary differential input pairs and the first reference voltage, wherein each of the auxiliary tail current source modules supplies a first auxiliary tail current to the corresponding first auxiliary differential input pair during a second time interval; and
a second operational amplifier, comprising:
a second primary differential input pair, having a common terminal, a first differential terminal, a second differential terminal, a first input terminal, and a second input terminal, wherein the first input terminal and the second input terminal respectively receive the first input signal and the second input signal that are differential to each other;
a second primary tail current source module, coupled between the common terminal of the second primary differential input pair and a second reference voltage, and supplying a second tail current to the second primary differential input pair during the second time interval;
M second auxiliary differential input pairs, wherein M is a positive integer, and each of the second auxiliary differential input pairs has a common terminal, a first differential terminal, a second differential terminal, a first input terminal, and a second input terminal, wherein the first input terminal and the second input terminal respectively receive the first input signal and the second input signal, and the first differential terminal and the second differential terminal are respectively coupled to the first differential terminal and the second differential terminal of the second primary differential input pair; and
M second auxiliary tail current source modules, respectively coupled between the common terminals of the second auxiliary differential input pairs and the second reference voltage, wherein each of the second auxiliary tail current source modules supplies a second auxiliary tail current to the corresponding second auxiliary differential input pair during the first time interval,
wherein the first time interval and the second time interval partially overlap each other.

12. The rail to rail operational amplifier according to claim 11, wherein the first reference voltage is a supply voltage, and the second reference voltage is a ground voltage.

13. The rail to rail operational amplifier according to claim 11 further comprising:
a first active load, coupled between the first differential terminal and the second differential terminal of the first primary differential input pair and the second reference voltage; and
a second active load, coupled between the first differential terminal and the second differential terminal of the second primary differential input pair and the second reference voltage, and coupled to a first differential terminal and a second differential terminal of the first active load.

14. The rail to rail operational amplifier according to claim 11, wherein
the first primary tail current source module is a first primary tail current source, the first primary tail current source is coupled between the common terminal of the first primary differential input pair and the first reference voltage, and the primary tail current source determines whether to generate the first tail current according to a first bias voltage,
the second primary tail current source module is a second primary tail current source, the second primary tail current source is coupled between the common terminal of the second primary differential input pair and the second reference voltage, and the primary tail current source determines whether to generate the second tail current according to a second bias voltage.

15. The rail to rail operational amplifier according to claim 14, wherein
each of the first auxiliary tail current source modules is a first auxiliary tail current source, each of the first auxiliary tail current sources is coupled between the common terminal of the corresponding first auxiliary differential input pair and the first reference voltage, and each of the auxiliary tail current sources generates the auxiliary tail current according to a third bias voltage,
each of the second auxiliary tail current source modules is a second auxiliary tail current source, each of the second auxiliary tail current sources is coupled between the common terminal of the corresponding second auxiliary differential input pair and the second reference voltage, and each of the second auxiliary tail current sources generates the second auxiliary tail current according to a fourth bias voltage.

16. The rail to rail operational amplifier according to claim 15 further comprising:
a first bias voltage supplier, receiving a first primary bias voltage and a switch control signal, and generating the first bias voltage during the first time interval and generating the second bias voltage during the second time interval by using the first primary bias voltage according to the switch control signal; and
a second bias voltage supplier, receiving a second primary bias voltage and the switch control signal, and generating the fourth bias voltage during the first time interval and generating the third bias voltage during the second time interval by using the second primary bias voltage according to the switch control signal.

17. The rail to rail operational amplifier according to claim 16, wherein the first bias voltage supplier comprises:
a first switch, having a control terminal for receiving a first switch control signal in the switch control signal, a first terminal for receiving the first reference voltage, and a second terminal for supplying the first bias voltage;
a second switch, having a first terminal coupled to the second terminal of the first switch, a second terminal for receiving the first primary bias voltage, and a control terminal for receiving an inverted signal of the first switch control signal;
a third switch, having a control terminal for receiving a second switch control signal in the switch control signal, a first terminal for receiving the first reference voltage, and a second terminal for supplying the third bias voltage; and
a fourth switch, having a first terminal coupled to the second terminal of the third switch, a second terminal for receiving the first primary bias voltage, and a control terminal for receiving an inverted signal of the second switch control signal,
the second bias voltage supplier comprises:
a fifth switch, having a control terminal for receiving the inverted signal of the first switch control signal, a first terminal for receiving the second reference voltage, and a second terminal for supplying the second bias voltage;
a sixth switch, having a first terminal coupled to the second terminal of the first switch, a second terminal for receiving the second primary bias voltage, and a control terminal for receiving the first switch control signal;
a seventh switch, having a control terminal for receiving the inverted signal of the second switch control signal, a first terminal for receiving the second reference voltage, and a second terminal for supplying the fourth bias voltage; and
an eighth switch, having a first terminal coupled to the second terminal of the third switch, a second terminal for receiving the second primary bias voltage, and a control terminal for receiving the second switch control signal.
